(19) United States
(12) Patent Application Publication
(10) Pub. No.: US 2026/0011015 A1
(43) Pub. Date: Jan. 8, 2026

(54) INFORMATION PROCESSING APPARATUS, INFORMATION PROCESSING METHOD, AND NON-TRANSITORY COMPUTER READABLE MEDIUM

(71) Applicant: NEC Corporation, Tokyo (JP)

(72) Inventors: Taichi OHTSUJI, Tokyo (JP); Kazuma NOGUCHI, Tokyo (JP)

(73) Assignee: NEC Corporation, Tokyo (JP)

(21) Appl. No.: 19/252,236

(22) Filed: Jun. 27, 2025

(30) Foreign Application Priority Data
Jul. 3, 2024 (JP) 2024-107284

(51) Int. Cl. G06T 7/10; G01S 13/89

(52) U.S. Cl. CPC G06T 7/10; G01S 13/89; G06T 2207/20021

(57) ABSTRACT

To enable appropriate detection even in a case where a signal to be detected exists across a plurality of divided images. Provided is an information processing apparatus includes: a division unit that divides a spectrum image of a received radio signal into a plurality of divided spectrum images including a first divided spectrum image and a second divided spectrum image; a detection unit that detects a first specific range including a first specific signal in the first divided spectrum image and a second specific range including a second specific signal in the second divided spectrum image; and an output unit that, in a case where the first specific signal and the second specific signal are included in a specific signal across the first divided spectrum image and the second divided spectrum image, outputs information based on the specific signal.

### INCORPORATION BY REFERENCE

This application is based upon and claims the benefit of priority from Japanese patent application No. 2024-107284, filed on Jul. 3, 2024, the disclosure of which is incorporated herein in its entirety by reference.

### TECHNICAL FIELD

The present disclosure relates to an information processing apparatus, an information processing method, and a program.

### BACKGROUND ART

Patent Literature 1 discloses a technique capable of further improving a processing speed by dividing spectrum data into M divided areas, converting the divided areas into partial spectrum images, and performing area estimation processing.

### CITATION LIST

### Patent Literature

[Patent Literature 1] Japanese Unexamined Patent Application Publication No. 2023-55315

### SUMMARY

However, in Patent Literature 1, for example, in a case where a signal to be detected exists at a boundary of a divided spectrum image, there is a possibility that detection accuracy of the signal decreases.

In view of the above-described problems, an example object of the present disclosure is to provide a technique capable of appropriately detecting even in a case where a signal to be detected exists across a plurality of divided images.

According to a first aspect of the present disclosure, there is provided an information processing apparatus including: a division unit that divides a spectrum image of a received radio signal into a plurality of divided spectrum images including a first divided spectrum image and a second divided spectrum image; a detection unit that detects a first specific range including a first specific signal in the first divided spectrum image and a second specific range including a second specific signal in the second divided spectrum image; and an output unit that, in a case where the first specific signal and the second specific signal are included in a specific signal across the first divided spectrum image and the second divided spectrum image, outputs information based on the specific signal.

According to a second aspect of the present disclosure, there is provided an information processing method including: dividing a spectrum image of a received radio signal into a plurality of divided spectrum images including a first divided spectrum image and a second divided spectrum image; detecting a first specific range including a first specific signal in the first divided spectrum image and a second specific range including a second specific signal in the second divided spectrum image; and in a case where the first specific signal and the second specific signal are included in a specific signal across the first divided spectrum image and the second divided spectrum image, outputting information based on the specific signal.

According to a third aspect of the present disclosure, there is provided a program for causing a computer to execute: dividing a spectrum image of a received radio signal into a plurality of divided spectrum images including a first divided spectrum image and a second divided spectrum image; detecting a first specific range including a first specific signal in the first divided spectrum image and a second specific range including a second specific signal in the second divided spectrum image; and in a case where the first specific signal and the second specific signal are included in a specific signal across the first divided spectrum image and the second divided spectrum image, outputting information based on the specific signal.

According to one aspect, even in a case where a signal to be detected exists across a plurality of divided images, detection can be appropriately performed.

### BRIEF DESCRIPTION OF DRAWINGS

The above and other aspects, features and advantages of the present disclosure will become more apparent from the following description of certain example embodiments when taken in conjunction with the accompanying drawings, in which:

FIG. 1 is a diagram illustrating an example of a configuration of an information processing apparatus according to some example embodiments;

FIG. 2 is a diagram illustrating a configuration example of an information processing system according to some example embodiments;

FIG. 3 is a diagram illustrating a hardware configuration example of the information processing apparatus according to some example embodiments;

FIG. 4 is a flowchart illustrating an example of processing of the information processing apparatus according to some example embodiments; and

FIG. 5 is a diagram illustrating an example of integration by combining the coordinate information according to some example embodiments.

### EXAMPLE EMBODIMENT

The principles of the present disclosure will be described with reference to some example embodiments. It is to be understood that the example embodiments have been described for purposes of illustration only and will aid those skilled in the art in understanding and carrying out the present disclosure without suggesting limitations on the scope of the present disclosure. The disclosure described in the present description is implemented in various methods other than those described below.

In the following description and claims, unless defined otherwise, all technical and scientific terms used in the present specification have the same meaning as commonly understood by those skilled in the art of the technical field to which the present disclosure belongs.

Hereinafter, some example embodiments of the present disclosure will be described with reference to the drawings. Each of the drawings is merely an example to illustrate one or more example embodiments. Each of the drawings is not associated with only one specific example embodiment, but may be associated with one or more other example embodiments. As those skilled in the art will appreciate, various features or steps described with reference to any one of the drawings may be combined with features or steps illustrated in one or more other drawings, for example, to create an example embodiment that is not explicitly illustrated or described. All of the features or steps illustrated in any one of the drawings for describing some example embodiments are not necessarily mandatory, and some features or steps may be omitted. The order of the steps described in any of the drawings may be changed as appropriate.

### First Example Embodiment

### <Configuration>

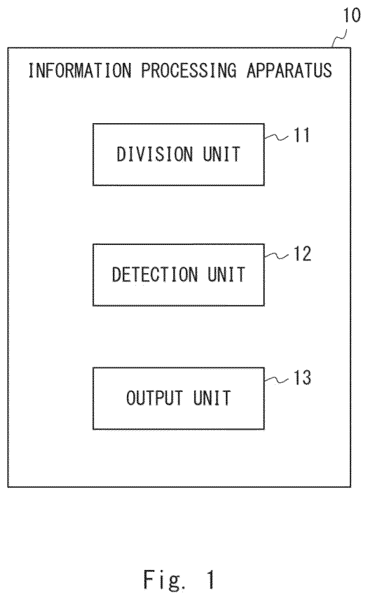

A configuration of an information processing apparatus 10 according to some example embodiments will be described with reference to FIG. 1. FIG. 1 is a diagram illustrating an example of a configuration of an information processing apparatus (teacher data generation apparatus) 10 according to some example embodiments. The information processing apparatus 10 includes a division unit 11, a detection unit 12, and an output unit 13. These units may be implemented by cooperation of one or more programs installed in the information processing apparatus 10 and hardware such as a processor and a memory of the information processing apparatus 10.

The division unit 11 divides the spectrum image of the received radio signal into a plurality of divided spectrum images including a first divided spectrum image and a second divided spectrum image. The detection unit 12 detects a first specific range including a first specific signal in the first divided spectrum image and a second specific range including a second specific signal in the second divided spectrum image.

In a case where the first specific signal and the second specific signal are included in a specific signal across the first divided spectrum image and the second divided spectrum image, the output unit 13 outputs information based on the specific signal.

### Second Example Embodiment

### <System Configuration>

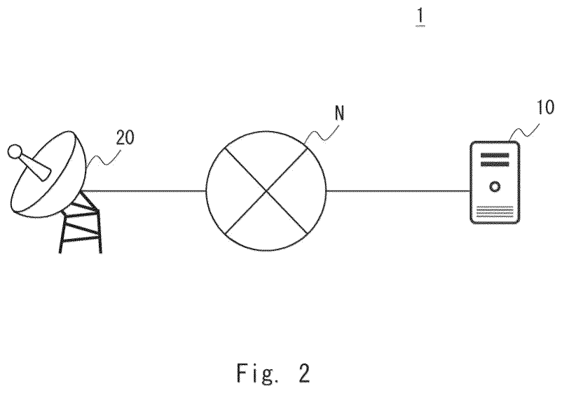

Next, a configuration of an information processing system 1 according to some example embodiments will be described with reference to FIG. 2. FIG. 2 is a diagram illustrating a configuration example of the information processing system 1 according to some example embodiments. In the example of FIG. 2, the information processing system 1 includes the information processing apparatus 10 and a reception apparatus 20. In the example of FIG. 2, the information processing apparatus 10 and the reception apparatus 20 are connected so as to be able to communicate with each other via a network N. The number of information processing apparatuses 10 and the number of reception apparatuses 20 are not limited to those in the example of FIG. 2.

Examples of the network N include the Internet, a mobile communication system, a wireless local area network (LAN), a LAN, and a bus. Examples of the mobile communication system include a fifth generation mobile communication system (5G), a sixth generation mobile communication system (6G and Beyond 5G), a fourth generation mobile communication system (4G), and a third generation mobile communication system (3G).

The information processing apparatus 10 is, for example, an apparatus such as a server, a cloud, a personal computer, or a smartphone. For example, the information processing apparatus 10 detects a specific signal to be detected from the received radio signal. Then, the information processing apparatus 10 may output information related to the specifying information to the user, for example.

The reception apparatus 20 includes a radio wave sensor that receives various radio signals. The reception apparatus 20 transmits spectrum data generated by performing Fourier transform on the received radio signal data to the information processing apparatus 10.

### <Hardware Configuration>

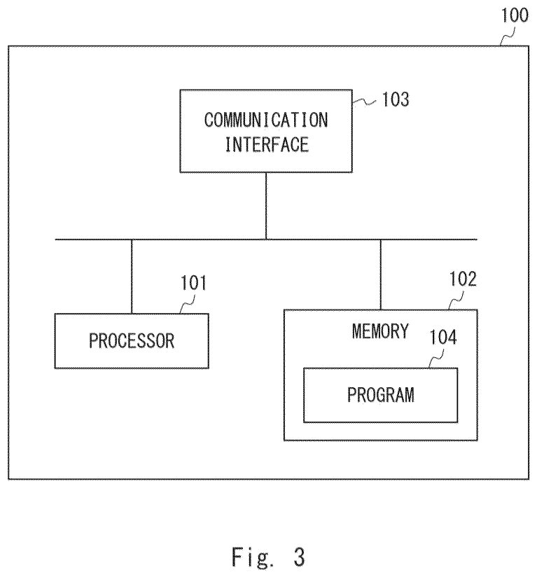

FIG. 3 is a diagram illustrating a hardware configuration example of the information processing apparatus 10 according to some example embodiments. In the example of FIG. 3, the information processing apparatus 10 (computer 100) includes a processor 101, a memory 102, and a communication interface 103. These units may be connected by a bus or the like. The memory 102 stores at least a part of a program 104. The communication interface 103 includes an interface necessary for communication with other network elements.

In case where the program 104 is executed by the cooperation of the processor 101, the memory 102, and the like, at least a part of processing according to some example embodiments of the present disclosure is performed by the computer 100. The memory 102 may be of any type. The memory 102 may be a non-transitory computer-readable storage medium, as a non-limiting example. The memory 102 may also be implemented using any suitable data storage technique such as a semiconductor-based memory device, a magnetic memory device and system, an optical memory device and system, a fixed memory, or a removable memory. Although only one memory 102 is illustrated in the computer 100, there may be several physically different memory modules in the computer 100. The processor 101 may be of any type. The processor 101 may include one or more of a general purpose computer, a dedicated computer, a microprocessor, a digital signal processor (DSP), and a processor based on a multi-core processor architecture as a non-limiting example. The computer 100 may include a plurality of processors such as application specific integrated circuit chips that are temporally dependent on a clock that synchronizes the main processor.

Some example embodiments of the present disclosure may be implemented in hardware or dedicated circuitry, software, logic, or any combination thereof. Some aspects may be implemented in hardware, while other aspects may be implemented in firmware or software that may be executed by a controller, a microprocessor or other computing devices.

The present disclosure also provides at least one computer program product tangibly stored on a non-transitory computer-readable storage medium. The computer program product includes computer-executable instructions, such as those included in a program module, and is executed on a device on a target real or virtual processor to perform the processes or methods of the present disclosure. The program module includes routines, programs, libraries, objects, classes, components, data structures, and the like that execute particular tasks or implement particular abstract data types. Functions of the program module may be combined or divided between the program modules as desired in some example embodiments. A machine-executable instruction of the program module can be executed in a local or distributed device. In the distributed device, the program modules can be located on both local and remote storage media.

Program codes for executing the methods of the present disclosure may be written in any combination of one or more programming languages. These program codes are provided to a processor or controller of a general purpose computer, a dedicated computer, or other programmable data processing apparatuses. In case where the program code is executed by the processor or controller, the functions/operations in the flowcharts and/or the implemented block diagrams are performed. The program code is executed entirely on a machine, partially on the machine as a stand-alone software package, partially on the machine and partially on a remote machine, or entirely on the remote machine or server.

The program can be stored and supplied to the computer using various types of non-transitory computer-readable media. The non-transitory computer-readable medium includes various types of tangible recording media. Examples of the non-transitory computer-readable medium include a magnetic recording medium, a magneto-optical recording medium, an optical disc medium, and a semiconductor memory. Examples of the magnetic recording medium include a flexible disk, a magnetic tape, and a hard disk drive. Examples of the magneto-optical recording medium include a magneto-optical disk. Examples of the optical disc medium include a Blu-ray disc, a compact disc (CD)-read only memory (ROM), a CD-recordable (R), and a CD-rewritable (RW). Examples of the semiconductor memory include a solid state drive, a mask ROM, a programmable ROM (PROM), an erasable PROM (EPROM), a flash ROM, and a random access memory (RAM). The program may be supplied to the computer using various types of transitory computer-readable media. Examples of the transitory computer-readable media include electrical signals, optical signals, and electromagnetic waves. The transitory computer-readable media can supply the programs to the computer via a wired communication path such as an electric wire and an optical fiber or a wireless communication path.

### <Processing>

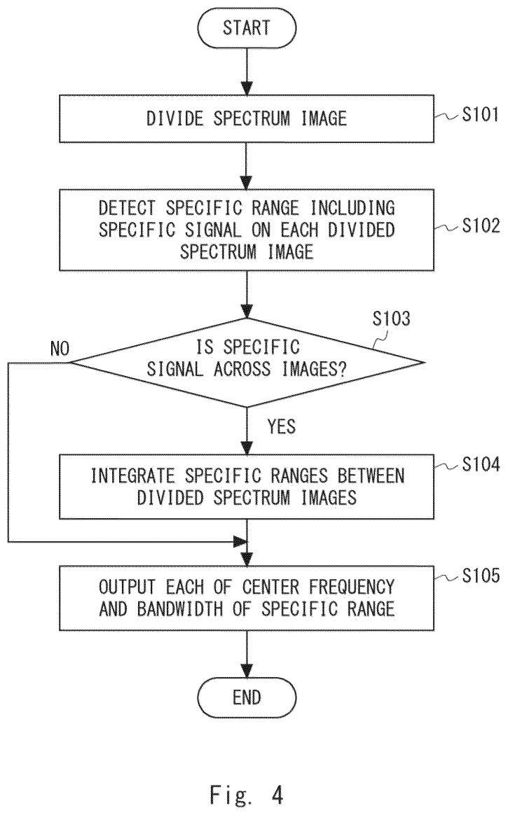

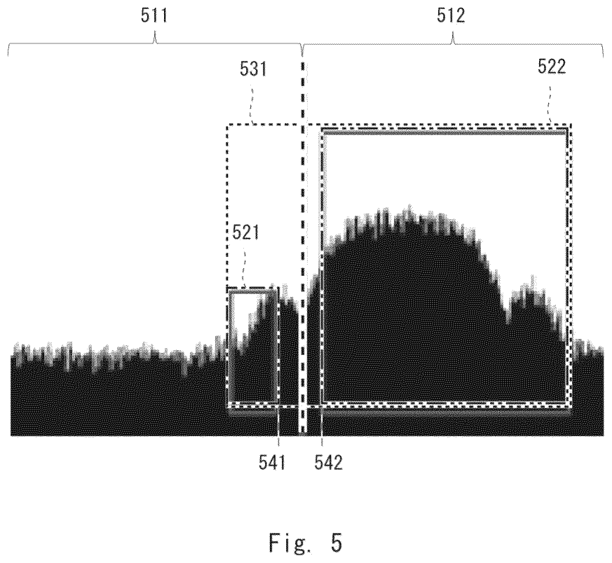

Next, an example of processing in the information processing apparatus 10 according to some example embodiments will be described with reference to FIGS. 4 and 5. FIG. 4 is a flowchart illustrating an example of the processing of the information processing apparatus 10 according to some example embodiments. FIG. 5 is a diagram illustrating an example of integration by combining the coordinate information according to some example embodiments. The processing of FIG. 4 may be executed, for example, in case where a predetermined operation is performed by the user.

In step S101, the division unit 11 divides the spectrum image of the radio signal received by the reception apparatus 20 into the divided spectrum images. Here, the spectrum image may be generated based on spectrum data generated by performing fast Fourier transform (FFT) processing on the reception signal. The division unit 11 may divide the spectrum image into N (N is an integer of 2 or more) divided spectrum images so as not to overlap each other.

Subsequently, the detection unit 12 performs detection processing for each of the divided spectrum images and detects a specific range (region) or the like including one or more specific signals on each of the divided spectrum images (step S102). Here, the detection unit 12 may also detect (estimate) information related to each specific signal from the divided spectrum image using artificial intelligence (AI) or the like, for example. Here, examples of the information related to the specific signal may include, for example, a signal type, a class, transmission source information, and the like of a digital communication wave, an analog communication wave, a non-communication wave, or the like.

The following processing is executed for each specific signal. Subsequently, the output unit 13 determines whether the specific signal is transmitted across the adjacent divided spectrum images (sharing the image end) (step S103). Here, the output unit 13 may determine whether the first specific signal detected from the first divided spectrum image and the second specific signal detected from the second divided spectrum image adjacent to the first divided spectrum image are the same signal. In this case, the output unit 13 may determine whether the first specific signal is interrupted at an end adjacent to the second divided spectrum image and the second specific signal is interrupted at an end adjacent to the first divided spectrum image of the image. Then, the output unit 13 may determine that the specific signal is across the adjacent divided spectrum images only in a case where these conditions are satisfied. In this case, for example, the output unit 13 may determine whether the distance (for example, a difference in coordinates in the lateral direction) between the end of the first specific region including the first specific signal and the end of the first divided spectrum image is within a threshold (for example, substantially the same). For example, the output unit 13 may determine whether the distance between the end of the second specific region including the second specific signal and the end of the second divided spectrum image is within a threshold. Then, in a case where these conditions are satisfied, the output unit 13 may determine that the specific signal is across the adjacent divided spectrum images.

For example, in a case where the distance between the end on the second divided spectrum image side of the first specific range including the first specific signal and the end on the first divided spectrum image side of the second specific range including the second specific signal is within a threshold, the output unit 13 may determine that the specific signal is across adjacent divided spectrum images.

FIG. 5 illustrates an example of a first specific range 521 including the first specific signal detected in a first divided spectrum image 511 and a second specific range 522 including the second specific signal detected in a second divided spectrum image 512. In the case of the example of FIG. 5, the output unit 13 may determine that the distance (difference in coordinates in the lateral direction) between an end 541 of the first specific range 521 on the second divided spectrum image 512 side and an end 542 of the second specific range 522 on the first divided spectrum image 511 side is within a threshold.

For example, in addition to the conditions described above, the output unit 13 may further determine whether the information related to the first specific signal detected by the detection unit 12 in the first divided spectrum image matches the information related to the second specific signal detected by the detection unit 12 in the second divided spectrum image. Then, in a case where these conditions are satisfied, the output unit 13 may determine that the specific signal is across the adjacent divided spectrum images.

For example, in addition to at least one of the conditions described above, the output unit 13 may further determine whether the difference between the power level (reception strength) of the first specific signal detected in the first divided spectrum image and the power level of the second specific signal detected in the second divided spectrum image is equal to or less than a threshold. Then, in a case where these conditions are satisfied, the output unit 13 may determine that the specific signal is across the adjacent divided spectrum images.

In this case, the output unit 13 may first determine a threshold NT for determining whether two signals near the boundary of the plurality of divided spectrum images are a single signal or different signals. For example, the output unit 13 may generate a histogram from spectrum data and determine a value obtained by adding a predetermined value D to a power level NO of the mode value as the threshold NT. The output unit 13 may calculate, for example, an average value A and a standard deviation c of the power level of the noise portion (for example, a region where the specific signal is not detected by the detection unit 12) in the spectrum data, and determine the threshold NT by the following Expression (1).

$$NT = A + c \times 2 \qquad ( 1 )$$

Then, for example, the output unit 13 may calculate a weighted average Pav of the power levels near the boundary of the plurality of divided spectrum images. In this case, the output unit 13 may set the weight of the weighted average to be higher as it is closer to the boundary of the plurality of divided spectrum images and lower as it is farther from the boundary. Then, for example, the output unit 13 may compare the calculated weighted average Pav of the power levels near the boundary with the threshold NT described above. Then, in a case where the weighted average Pav of the power levels near the boundary is less than the threshold NT, the output unit 13 may determine that two signals near the boundary of the plurality of divided spectrum images are different signals. On the other hand, in a case where the weighted average Pav of the power levels near the boundary is equal to or greater than the threshold NT, the output unit 13 may determine that two signals near the boundary of the plurality of divided spectrum images are the same signal. As a result, for example, even in a case where each specific range (bounding box) detected by the detection unit 12 is inside the boundary between both images as illustrated in FIG. 5, it is possible to appropriately determine whether to integrate.

In a case where the specific signal is not across the plurality of divided spectrum images (NO in step S103), the process proceeds to step S105. On the other hand, in a case where the specific signal is across the plurality of divided spectrum images (YES in step S103), the output unit 13 integrates the specific ranges including the specific signal between the adjacent divided spectrum images (step S104). As a result, for example, in a case where there is a range including the specific signal at the boundary of the plurality of divided images, it is possible to achieve both improvement in signal detection accuracy (in particular, estimation accuracy of the center frequency) and prevention of a decrease in processing speed.

### (Example of Integration by Combining Coordinate Information)

For example, the output unit 13 may combine coordinate information indicating a range including each specific signal detected in each divided spectrum image. In this case, for example, the output unit 13 may determine an end that is not on the second divided spectrum image side among both ends of the first specific range as the coordinates of an end on one end side of the integrated specific range. Then, for example, the output unit 13 may determine an end that is not on the first divided spectrum image side among both ends of the second specific range as the coordinates of an end on the other end side of the integrated specific range.

In this case, in the example of FIG. 5, for example, the output unit 13 may set the coordinates at the lower left corner of the first specific range 521 as the coordinates at the lower left corner of an integrated specific range 531, and may set the coordinates at the upper right corner of the second specific range 522 as the coordinates at the upper right corner of the integrated specific range 531.

### (Example of Combining and Re-Detecting Images for Integration)

For example, the output unit 13 may combine a plurality of adjacent divided spectrum images and integrate the plurality of divided spectrum images by causing the detection unit 12 to detect the specific range including the specific signal again based on the combined image. As a result, the signal detection accuracy can be further improved.

In this case, for example, the output unit 13 may combine (generate) images of the central portions of a plurality of adjacent divided spectrum images. In this case, the image of the central portion may be, for example, an image in which a half of the first divided spectrum image on a side in contact with the second divided spectrum image and a half of the second divided spectrum image on a side in contact with the first divided spectrum image are combined.

Subsequently, the output unit 13 outputs the center frequency and the bandwidth of each specific range including each specific signal (step S105). Here, in a case where the divided spectrum images are integrated, the output unit 13 may calculate the bandwidth and the center frequency of the specific signal based on the coordinate information after the integration.

### <Detection Example Using Machine Learning>

In step S102 of FIG. 4, the detection unit 12 may detect the specific range including the specific signal based on the divided spectrum image by using the learned model generated by the machine learning. In this case, the division unit 11 may acquire a data set of a combination of the spectrum image and the data indicating the specific range input by the operator.

Then, the division unit 11 may divide the spectrum image into the divided spectrum images and divide the specific range into the divided specific ranges according to the ranges included in the divided spectrum images. Then, the detection unit 12 may perform supervised machine learning using a combination of the divided spectrum image and the divided specific range included in the divided spectrum image as learning data.

### (Others)

In a case where the specific region including the specific signal is directly detected from the broadband spectrum image having high resolution, the time required for the detection (inference) processing increases because the number of pixels is large. Therefore, for example, the time required for the detection may exceed the time for which the delay is allowed.

On the other hand, in a case where the detection processing is performed for each of the divided spectrum images (sub-images) obtained by dividing the spectrum image, detection (inference) can be performed in parallel, so that the time required for detection (delay time) can be shortened. However, in a case where a detection target signal (specific signal) exists at a boundary between adjacent divided spectrum images, coordinate information, a class number, and the like of the inference result are independently output for each divided spectrum image. Therefore, the estimation accuracy of the coordinate information and the center frequency may be deteriorated.

As described above, according to the present disclosure, signals across adjacent split spectrum images are integrated. Therefore, even in a case where a signal to be detected exists across a plurality of divided images, detection can be appropriately performed.

### Modified Example

The information processing apparatus 10 may be an apparatus contained in one housing, but the information processing apparatus 10 of the present disclosure is not limited thereto. Each unit of the information processing apparatus 10 may be implemented by, for example, cloud computing including one or more computers. The information processing apparatus 10 and the reception apparatus 20 may be housed in the same housing and configured as an integrated information processing apparatus. At least a part of the processing of each functional unit of the information processing apparatus 10 may be executed by the reception apparatus 20. Such an information processing apparatus 10 is also included in an example of the “information processing apparatus” of the present disclosure.

While the present disclosure has been particularly shown and described with reference to example embodiments thereof, the present disclosure is not limited to these example embodiments. It will be understood by those of ordinary skill in the art that various changes in form and details may be made therein without departing from the spirit and scope of the present disclosure as defined by the claims. And each example embodiment can be appropriately combined with other example embodiments.

Some or all of the above-described example embodiments may be described as the following supplementary notes, but are not limited to the following supplementary notes. Some or all of the elements (for example, configurations and functions) described in each supplementary note dependent on Supplementary Note 1 can also be dependent on independent supplementary notes of other categories by the same dependency relationship. Some or all of the elements described in any Supplementary Note may be applied to various types of hardware, software, recording means for recording software, systems, and methods.

### (Supplementary Note 1)

An information processing apparatus including:
a division unit that divides a spectrum image of a received radio signal into a plurality of divided spectrum images including a first divided spectrum image and a second divided spectrum image;
a detection unit that detects a first specific range including a first specific signal in the first divided spectrum image and a second specific range including a second specific signal in the second divided spectrum image; and
an output unit that, in a case where the first specific signal and the second specific signal are included in a specific signal across the first divided spectrum image and the second divided spectrum image, outputs information based on the specific signal.

### (Supplementary Note 2)

The information processing apparatus according to Supplementary Note 1, in which the output unit determines that the first specific signal and the second specific signal are included in the specific signal across the first divided spectrum image and the second divided spectrum image in a case where a distance between an end of a first specific region including the first specific signal and an end of the first divided spectrum image is within a threshold and a distance between an end of a second specific region including the second specific signal and an end of the second divided spectrum image is within a threshold.

### (Supplementary Note 3)

The information processing apparatus according to Supplementary Note 1, in which the output unit determines that the first specific signal and the second specific signal are included in the specific signal across the first divided spectrum image and the second divided spectrum image in a case where a distance between an end on the second divided spectrum image side of the first specific range including the first specific signal and an end on the first divided spectrum image side of the second specific range including the second specific signal is within a threshold.

### (Supplementary Note 4)

The information processing apparatus according to Supplementary Note 2 or 3, in which
the detection unit detects information related to the first specific signal based on the first divided spectrum image, and detecting information related to the second specific signal based on the second divided spectrum image, and
the output unit further determines that the first specific signal and the second specific signal are included in the specific signal across the first divided spectrum image and the second divided spectrum image in a case where the detected information related to the first specific signal matches the detected information related to the second specific signal.

### (Supplementary Note 5)

The information processing apparatus according to Supplementary Note 2 or 3, in which the output unit further determines that the first specific signal and the second specific signal are included in the specific signal across the first divided spectrum image and the second divided spectrum image in a case where a weighted average of power levels near a boundary between the first divided spectrum image and the second divided spectrum image is equal to or greater than a threshold.

### (Supplementary Note 6)

The information processing apparatus according to Supplementary Note 1 or 2, in which the output unit determines an end that is not on the second divided spectrum image side among both ends of the first specific range as an end on one end side of a specific range in which the specific signal is included, and an end that is not on the first divided spectrum image side among both ends of the second specific range as an end on another end side of the specific range.

### (Supplementary Note 7)

The information processing apparatus according to Supplementary Note 1 or 2, in which the detection unit detects a specific range including the specific signal based on an image obtained by combining the first divided spectrum image and the second divided spectrum image.

### (Supplementary Note 8)

The information processing apparatus according to Supplementary Note 1 or 2, in which the output unit outputs information indicating a bandwidth and a center frequency of the specific signal.

### (Supplementary Note 9)

An information processing method including:
dividing a spectrum image of a received radio signal into a plurality of divided spectrum images including a first divided spectrum image and a second divided spectrum image;
detecting a first specific range including a first specific signal in the first divided spectrum image and a second specific range including a second specific signal in the second divided spectrum image; and
in a case where the first specific signal and the second specific signal are included in a specific signal across the first divided spectrum image and the second divided spectrum image, outputting information based on the specific signal.

### (Supplementary Note 10)

A program for causing a computer to execute:
dividing a spectrum image of a received radio signal into a plurality of divided spectrum images including a first divided spectrum image and a second divided spectrum image;
detecting a first specific range including a first specific signal in the first divided spectrum image and a second specific range including a second specific signal in the second divided spectrum image; and
in a case where the first specific signal and the second specific signal are included in a specific signal across the first divided spectrum image and the second divided spectrum image, outputting information based on the specific signal.

What is claimed is:

1. An information processing apparatus comprising:
a memory configured to store instructions; and
a processor configured to execute the instructions to:
divide a spectrum image of a received radio signal into a plurality of divided spectrum images including a first divided spectrum image and a second divided spectrum image;
detect a first specific range including a first specific signal in the first divided spectrum image and a second specific range including a second specific signal in the second divided spectrum image; and
in a case where the first specific signal and the second specific signal are included in a specific signal across the first divided spectrum image and the second divided spectrum image, output information based on the specific signal.

2. The information processing apparatus according to claim 1, wherein the processor is configured to execute the instructions to determine that the first specific signal and the second specific signal are included in the specific signal across the first divided spectrum image and the second divided spectrum image in a case where a distance between an end of a first specific region including the first specific signal and an end of the first divided spectrum image is within a threshold and a distance between an end of a second specific region including the second specific signal and an end of the second divided spectrum image is within a threshold.

3. The information processing apparatus according to claim 1, wherein the processor is configured to execute the instructions to determine that the first specific signal and the second specific signal are included in the specific signal across the first divided spectrum image and the second divided spectrum image in a case where a distance between an end on the second divided spectrum image side of the first specific range including the first specific signal and an end on the first divided spectrum image side of the second specific range including the second specific signal is within a threshold.

4. The information processing apparatus according to claim 2, wherein the processor is configured to execute the instructions to:
detect information related to the first specific signal based on the first divided spectrum image;
detect information related to the second specific signal based on the second divided spectrum image; and
determine that the first specific signal and the second specific signal are included in the specific signal across the first divided spectrum image and the second divided spectrum image in a case where the detected information related to the first specific signal matches the detected information related to the second specific signal.

5. The information processing apparatus according to claim 2, wherein the processor is configured to execute the instructions to determine that the first specific signal and the second specific signal are included in the specific signal across the first divided spectrum image and the second divided spectrum image in a case where a weighted average of power levels near a boundary between the first divided spectrum image and the second divided spectrum image is equal to or greater than a threshold.

6. The information processing apparatus according to claim 1, wherein the processor is configured to execute the instructions to determine an end that is not on the second divided spectrum image side among both ends of the first specific range as an end on one end side of a specific range in which the specific signal is included, and an end that is not on the first divided spectrum image side among both ends of the second specific range as an end on another end side of the specific range.

7. The information processing apparatus according to claim 1, wherein the processor is configured to execute the instructions to detect a specific range including the specific signal based on an image obtained by combining the first divided spectrum image and the second divided spectrum image.

8. The information processing apparatus according to claim 1, wherein the processor is configured to execute the instructions to output information indicating a bandwidth and a center frequency of the specific signal.

9. An information processing method comprising:
dividing a spectrum image of a received radio signal into a plurality of divided spectrum images including a first divided spectrum image and a second divided spectrum image;
detecting a first specific range including a first specific signal in the first divided spectrum image and a second specific range including a second specific signal in the second divided spectrum image; and
in a case where the first specific signal and the second specific signal are included in a specific signal across the first divided spectrum image and the second divided spectrum image, outputting information based on the specific signal.

10. A non-transitory computer-readable medium storing a program for causing a computer to execute:
dividing a spectrum image of a received radio signal into a plurality of divided spectrum images including a first divided spectrum image and a second divided spectrum image;
detecting a first specific range including a first specific signal in the first divided spectrum image and a second specific range including a second specific signal in the second divided spectrum image; and
in a case where the first specific signal and the second specific signal are included in a specific signal across the first divided spectrum image and the second divided spectrum image, outputting information based on the specific signal.
